(19) United States
(12) Patent Application Publication
(10) Pub. No.: US 2025/0301687 A1
(43) Pub. Date: Sep. 25, 2025

(54) III-Nitride Semiconductor Devices with Reduced Effective Size

(71) Applicant: Finwave Semiconductor, Inc., Belmont, MA (US)

(72) Inventors: Hal Emmer, Wayland, ME (US); Bin Lu, Fremont, CA (US)

(21) Appl. No.: 19/061,278

(22) Filed: Feb. 24, 2025

Related U.S. Application Data
(60) Provisional application No. 63/568,520, filed on Mar. 22, 2024.

(51) Int. Cl. H10D 30/47; H10D 62/85; H10D 64/64

(52) U.S. Cl. CPC H10D 30/475; H10D 62/8503; H10D 64/64

(57) ABSTRACT

A new semiconductor structure is disclosed. The semiconductor structure includes an active region that is made narrower through the application of a p-type cap layer disposed thereupon. The p-type cap layer may be disposed on one side of the active region, or on both sides of the active region. This p-type cap layer may be applied to various semiconductor structures, including transistors, diodes and semiconductor resistors.

This application claims priority to U.S. Provisional Patent Application Ser. No. 63/568,520, filed Mar. 22, 2024, the disclosure of which is incorporated herein by reference in its entirety.

### FIELD

Embodiments of the present disclosure relate to a semiconductor structure and methods for making a semiconductor structure with a reduced effective width.

### BACKGROUND

FIGS. 1A-1B show a typical conventional depletion mode III-Nitride semiconductor transistor. FIG. 1A is a top view, while FIG. 1B is a cross-sectional view. The depletion mode III-Nitride semiconductor transistor comprises a substrate 1, a buffer layer 2 on top of the substrate 1, a GaN channel layer 3 on top of the buffer layer 2 and AlGaN barrier layer 4 on top of the channel layer 3. The substrate 1 is SiC, sapphire, Si or free-standing GaN semiconductors. A nucleation layer exists between the buffer layer 2 and the substrate 1. The barrier layer 4, which may be made from AlGaN, has a wider band-gap than the channel layer 3, which may be made from GaN. Source electrode 7 and drain electrode 8 are disposed on opposite sides of the gate electrode 6 in the length direction. The direction that is orthogonal to the length direction and perpendicular to the page in FIG. 1B is referred to as the width direction. This is the vertical direction in FIG. 1A. Note that in the depletion mode transistor, the two dimensional electron gas (2DEG) is disposed in the interface between the channel layer 3 and the barrier layer 4 and extends from the source electrode 7 to the drain electrode 8. Thus, this transistor conducts current between the source electrode 7 and the drain electrode 8 whenever the voltage applied to the gate electrode 6 is greater than a threshold voltage (Vtd) of the depletion mode transistor, which is a negative voltage.

FIGS. 1C-1D show a typical conventional enhancement mode III-Nitride semiconductor transistor. FIG. 1C is a top view, while FIG. 1D is a cross-sectional view. The structure of the enhancement mode transistor is: similar to that described above for the depletion mode transistor. However, a p-type cap layer 9 is disposed between the gate electrode 6 and the barrier layer 4. This p-type cap layer 9 may be GaN, doped with Mg, for example.

This p-type cap layer 9 serves to deplete the 2DEG beneath the p-type cap layer 9, as shown in FIG. 1D. To allow current to flow between the source electrode 7 and the drain electrode 8, the gate electrode 6 must be biased at a voltage greater than the threshold voltage (Vte) of the enhancement mode transistor, which is a positive voltage.

FIG. 2 shows a schematic of a conventional semiconductor resistor 10 where the resistance between port 11 and 12 is set by the semiconductor sheet resistance Rsh and the length and width of the active region between port 11 and 12.

In both devices, the active regions within which the electric current flows are typically defined by ion implantation isolation or etch-isolation (also called mesa-etch) outside of the active regions. The minimum width of the active regions for these devices, which include transistors, diodes or resistors, is limited by the process design rules such as the minimum allowable size of active masked area.

This minimum achievable active region width limits the performance of integrated circuits using the semiconductor resistors, transistors and diodes.

Therefore, it would be beneficial if there were new semiconductor structures that included narrower active regions for these various semiconductor devices.

### SUMMARY

A new semiconductor structure is disclosed. The semiconductor structure includes an active region that is made narrower through the application of a p-type cap layer disposed thereupon. The p-type cap layer may be disposed on one side of the active region, or on both sides of the active region. This p-type cap layer may be applied to various semiconductor structures, including transistors, diodes and semiconductor resistors.

According to one embodiment, a semiconductor transistor for use in a III-Nitride (III-N) semiconductor device is disclosed. The semiconductor transistor comprises a channel layer; a barrier layer located on the channel layer in a height direction, wherein electrons are formed at an interface between the channel layer and the barrier layer; a source electrode and a drain electrode, wherein a direction between the source electrode and the drain electrode is a length direction; and a gate electrode disposed between the source electrode and the drain electrode in the length direction and extending in a width direction, defining a gate region; such that the gate region comprises one or more depletion mode gate regions and one or more enhancement mode gate regions. In some embodiments, an effective width of the semiconductor transistor is equal to a width of the one or more depletion mode gate regions. In some embodiments, a p-type cap layer is disposed on a portion of the barrier layer in the gate region to create the one or more enhancement mode gate regions. In certain embodiments, the p-type cap layer comprises a Mg-doped GaN layer. In certain embodiments, the gate electrode is electrically isolated from the p-type cap layer. In certain embodiments, the gate electrode does not extend over the p-type cap layer. In certain embodiments, the gate electrode extends over the p-type cap layer and is electrically connected to the p-type cap layer. In certain embodiments, the one or more depletion mode gate regions are enabled when a voltage applied to the gate electrode is greater than a negative threshold voltage (Vtd) and the one or more enhancement mode gate regions are enabled when the voltage applied to the gate electrode is greater than a positive threshold voltage (Vte), and wherein the voltage applied to the gate electrode is switched between a voltage that is less than the negative threshold voltage and a voltage that is greater than the negative threshold voltage and less than the positive threshold voltage. In some embodiments, the gate region comprises two enhancement mode gate regions disposed on opposite sides of the depletion mode gate region in the width direction. In some embodiments, the gate region comprises one enhancement mode gate region adjacent to the depletion mode gate region in the width direction. In some embodiments, the gate region comprises two depletion mode gate regions disposed on opposite sides of the enhancement mode gate region in the width direction. In some embodiments, the enhancement mode gate region is created by etching to partially or completely remove the barrier layer in a portion of the gate region.

According to another embodiment, a semiconductor diode for use in a III-Nitride (III-N) semiconductor device is disclosed. The semiconductor diode comprises a channel layer; a barrier layer located on the channel layer in a height direction, wherein electrons are formed at an interface between the channel layer and the barrier layer; a anode and a cathode, wherein a region between the anode and the cathode is an active region; and a p-type cap layer disposed on top of a portion of the active region extending from the anode to the cathode. In some embodiments, an effective width of the semiconductor diode is equal to a width of the active region less the width of the p-type cap layer. In some embodiments, the p-type cap layer is disposed on both side of the active region in a width direction.

According to another embodiment, a semiconductor resistor for use in a III-Nitride (III-N) semiconductor device is disclosed. The semiconductor resistor comprises a first port and a second port; a channel layer; a barrier layer located on the channel layer in a height direction, wherein electrons are formed at an interface between the channel layer and the barrier layer; wherein a region between the first port and the second port defines an active region; and a p-type cap layer disposed on top of a portion of the active region extending from the first port to the second port; wherein a resistance of the semiconductor resistor is determined based on a length of the active region, wherein the length is defined as a distance from the first port to the second port, an effective width of the active region and a sheet resistance of the active region. In some embodiments, the p-type cap layer is disposed on both sides of the active region in a width direction. In some embodiments, the p-type cap layer is disposed on one side of the active region in a width direction. In some embodiments, the effective width of the active region is equal to the width of the active region less the width of the p-type cap layer.

### BRIEF DESCRIPTION OF THE FIGURES

For a better understanding of the present disclosure, reference is made to the accompanying drawings, which are incorporated herein by reference and in which:

FIGS. 1A-1B show a top view and a cross-section view, respectively, of a conventional depletion mode III-Nitride transistor according to the prior art;

FIGS. 1C-1D show a top view and a cross-section view, respectively, of a conventional enhancement mode III-Nitride transistor according to the prior art;

FIG. 2 shows a semiconductor resistor according to the prior art;

FIGS. 3A-3D show the top view and several cross-sectional views, respectively of the disclosed III-Nitride transistor according to one embodiment;

FIG. 4 shows the top view of the disclosed III-Nitride diode according to one embodiment; and

FIGS. 5A-5B show the top view of the disclosed III-Nitride semiconductor resistor according to two embodiments.

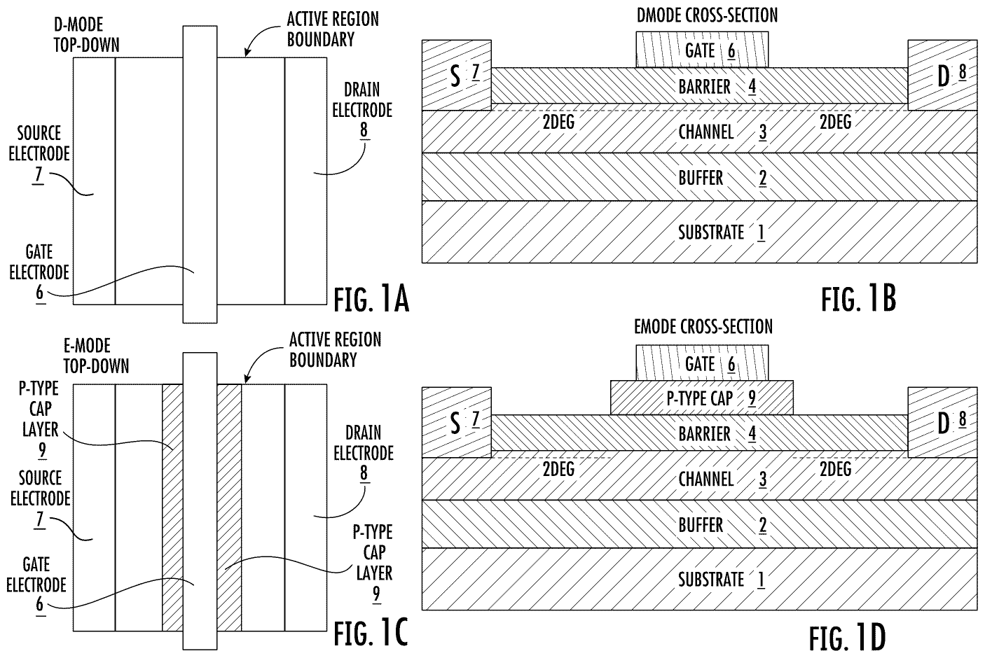

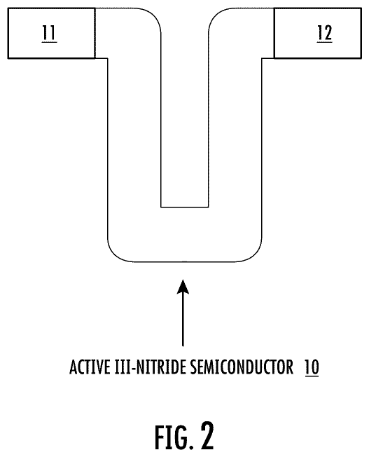

### DETAILED DESCRIPTION

This disclosure describes a semiconductor structure with a narrower active region.

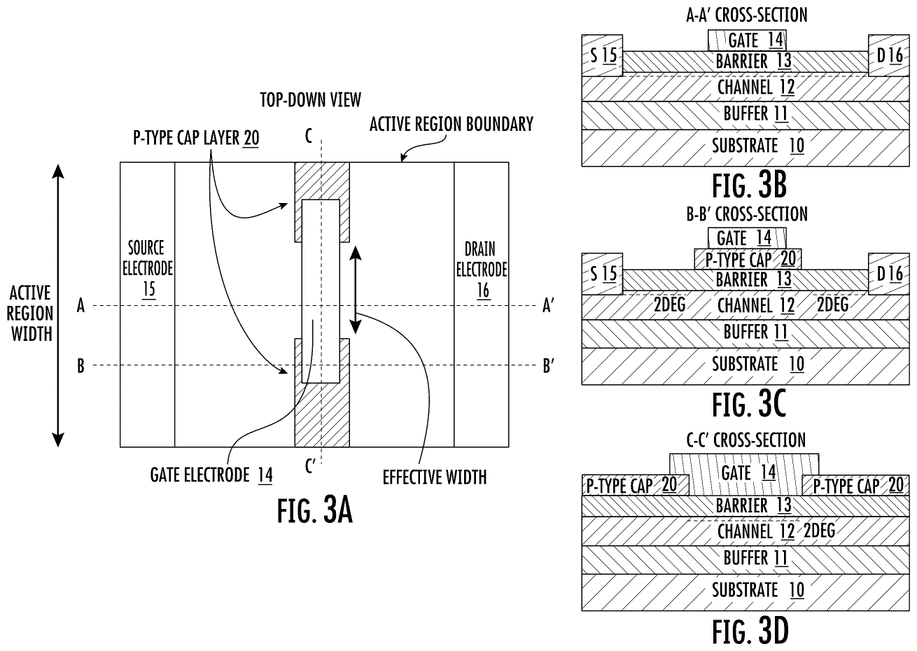

According to one embodiment, shown in FIGS. 3A-3D, the semiconductor structure is a depletion mode transistor. This depletion mode transistor includes a substrate 10, a buffer layer 11, a channel layer 12, and a barrier layer 13. These figures represent a transistor; however, this disclosure also applies to diodes. FIG. 3A represents a top view of the transistor structure, while FIG. 3B represents a cross-sectional view along line A-A′, FIG. 3C represents a cross-sectional view along line B-B′ and FIG. 3D represents a cross-sectional view along line C-C′. In some embodiments, a nucleation layer (not shown) may be disposed between the substrate 10 and the buffer layer 11.

The substrate 10 may be SiC, sapphire, Si, free-standing GaN or any other substrate including multiple layers including polycrystalline AlN. A nucleation layer may be disposed between the buffer layer 11 and surface of the substrate 10. The nucleation layer may include AlN.

A buffer layer 11 is formed over the nucleation layer. The buffer layer 11 may have a thickness between 0.5 nm and several microns, although other thicknesses are within the scope of the disclosure. The buffer layer 11 may comprise III-nitride semiconductors including GaN, AlGaN, InGaN, InAlN, InAlGaN and AlN.

A channel layer 12 is formed over the buffer layer 11. The channel layer 12 comprises a semiconductor material selected from AlGaN, InGaN, GaN, or any other suitable semiconductor material or combination of materials.

Carriers, which may be free electrons arranged as a two dimensional electron gas (2DEG), may exist in the certain portions of the channel layer 12 to conduct electrical current between the drain electrode 16 and the source electrode 15.

The channel layer 12 may comprise a single layer such as a GaN layer, or multiple layers. In one example, the channel layer 12 comprises a back-barrier structure, such as a GaN layer over an AlGAN layer (GaN/AlGaN) or a GaN layer over an InGaN layer and another GaN layer (GaN/InGaN/GaN). In another example, the channel layer 12 has a superlattice structure formed by repeating a bi-layer structure of AlGaN/GaN or AlN/GaN. The thickness of the channel layer 12 may be greater than 5 nm, such as between 50 nm and 400 nm, although other thicknesses may be used.

A barrier layer 13 is formed over the channel layer 12. The barrier layer 13 may be made of III-nitride semiconductors selected from AlGaN, InAlN, AlN, AlScN or InAlGaN with a non-zero aluminum content. The barrier layer 13 may be un-doped, or doped with Si or other impurities. The barrier layer 13 has a wider band-gap than the channel layer 12. The barrier layer 13 may be between 0.2 nm and 30 nm. A thin barrier layer, such as less than 10 nm, may be utilized. The barrier layer 13 may contain sub-layers. For example, a sub-layer of AlN may be adjacent to the channel layer 12 and a AlGaN or InAlN sublayer may be disposed on top of the AlN sublayer.

The top of the semiconductor structure includes a gate electrode 14, a source electrode 15 and a drain electrode 16. The region that is aligned with the gate electrode is referred to as the gate region.

In this embodiment, a p-type cap layer 20 is disposed beneath portions of the gate electrode 14 in the width direction. As noted above, the direction from the source electrode 15 to the drain electrode 16 is referred to as the length direction and the direction perpendicular to this (which is vertical in FIG. 3A) is referred to as the width direction.

This configuration creates a depletion mode gate region between two enhancement mode gate regions. Specifically, the cross-section shown in FIG. 3B, the gate electrode 14 is disposed directly on the barrier layer 13, creating a depletion mode gate region. In the cross-section shown in FIG. 3C, the gate electrode 14 is separated from the barrier layer 13 by the p-type cap layer 20, creating an enhancement mode gate region. In other words, the two sides of the gate region behave in enhancement mode, since there is a p-type cap layer 20 disposed beneath the gate electrode 14. The p-type cap layer 20 may be a Mg-doped GaN layer, in some embodiments. Alternatively, it may be Mg-doped AlGaN, InN or InGaN. Alternatively, the p-type cap layer 20 which forms the enhancement mode gate region may be replaced by another suitable method of forming an enhancement mode gate, such as recess etching to partially or fully remove the barrier layer 13 in that portion of the gate region. The p-type cap layer 20 may have a thickness from 5 nm to over 200 nm. The center portion of the gate region behaves in depletion mode, since there is no p-type cap layer 20 in this region. Thus, the width of the depletion mode gate region is smaller than the active width of the transistor, which is typically defined by the widths of the gate electrode 14, the source electrode 15 and the drain electrode 16. In other words, the effective width of the active region is reduced to the width of the depletion mode gate region. In some embodiments, this reduction in width may be 30% or more. Further, in certain embodiments, the active width of the transistor may be between 0.5 and 10 μm, while the width of the depletion mode gate region may be as small as 100 nm.

In operation, if the voltage applied to the gate electrode 14 is less than the threshold voltage of the depletion mode gate region (Vtd), the transistor will be turned off. Further, if the voltage applied to the gate electrode 14 is greater than the threshold voltage of the enhancement mode gate region (Vte), both the enhancement gate regions and the depletion mode gate regions will allow the flow of current. Importantly, if the voltage applied to the gate electrode 14 is greater than Vtd and less than Vte, only the depletion mode gate region will allow the flow of current.

As a result, a depletion mode transistor with a smaller channel width than one with an active width defined only through conventional implant-isolation may be realized. Using this method, the effective depletion mode width can be reduced to smaller dimensions than those which are achievable with available processes using the conventional isolation method alone.

The enhancement mode gate regions may be electrically connected to the gate electrode 14, as shown in FIGS. 3A-3D. In another embodiment, the enhancement mode gate regions may be electrically isolated from the gate electrode 14 so that these enhancement mode gate regions are always turned off.

In some embodiments, as shown in FIGS. 3A-3D, the gate electrode 14 may partially overlap the p-type cap layer 20. In other embodiments, the gate electrode 14 may completely overlap the p-type cap layer 20, or may extend beyond the p-type cap layer 20. In yet other embodiments, such as when the enhancement gate regions are electrically isolated, the gate electrode 14 may not be present over the p-type cap layer 20 at all.

Further, while FIGS. 3A-3D show the depletion mode gate region surrounded by enhancement mode gate regions on both sides, other embodiments are possible. For example, the enhancement mode gate region may be located on only one side of the transistor, such as at the top or bottom of FIG. 3A. In another embodiment, the p-type cap layer 20 may have two or more gaps, such that there are multiple depletion mode gate regions. In yet another embodiment, the p-type cap layer 20 may be located in the middle of the gate region with depletion mode gate regions located on both sides of the enhancement mode gate region.

Further, while FIG. 3A-3D show the p-type cap layer 20 only disposed in the gate region, it is understood that the p-type cap layer 20 may extend from the gate region toward the source electrode 15 and/or the drain electrode 16.

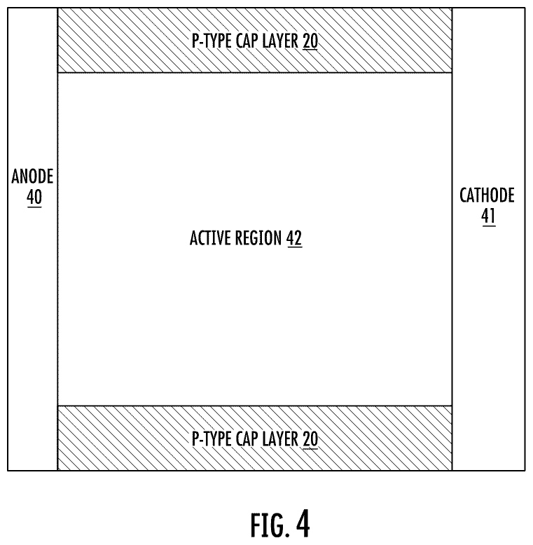

Note that this technique may also be applied to diodes, as shown in FIG. 4. Although not shown, the cross-section view of the diode comprises a substrate, buffer layer, channel layer and a barrier layer, as described above. The anode 40 may be in Schottky contact with the barrier layer; while the cathode 41 may be disposed in an ohmic recess in contact with the barrier layer. In this embodiment, the p-type cap layer 20 may extend from the anode 40 to the cathode 41 across one or more portions of the active region 42. In FIG. 4, the p-type cap layer 20 extends from the anode 40 to the cathode 41 at the top and bottom of the active region 42. In other embodiments, the p-type cap layer 20 may be located only on one side or may be disposed in the middle of the active region 42. Thus, in this embodiment, the effective width of the diode becomes equal to the width of the active region 42 less the width of the p-type cap layer 20.

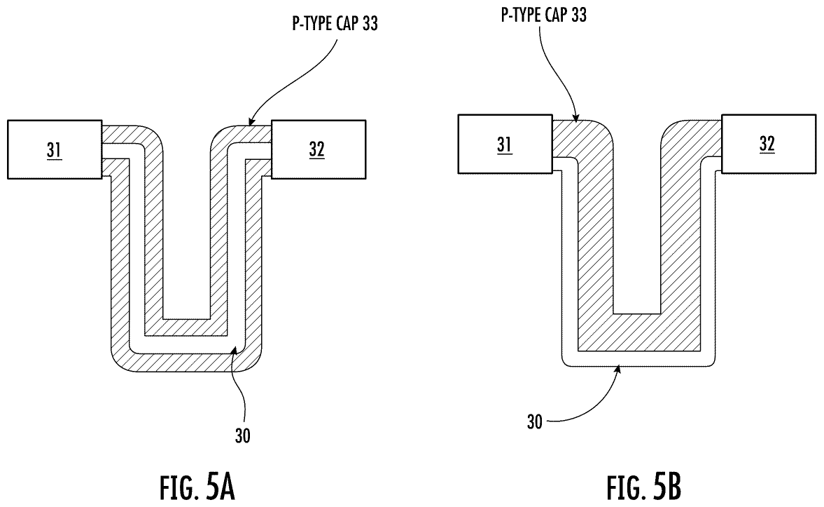

This technique may also be applied to semiconductor resistors. FIGS. 5A-5B show two embodiments. In these figures, the semiconductor resistor comprises an active region 30 that is shaped in a serpentine pattern between first port 31 and second port 32. However, note that the active region 30 may have any suitable shape. The active region 30 may have the same cross-section as the transistor described above. The P-type cap layer 33 is disposed on a portion of the top surface of the active region 30, and extends along the entire length of the semiconductor resistor. In FIG. 5A, the p-type cap layer 33 is disposed on both sides of the active region 30 (in the width direction), while in FIG. 5B, the p-type cap layer 33 is only disposed on one side of the active region 30. Note that the p-type cap layer 33 may be larger, smaller, or the same size as the active region 30. Because the p-type cap layer 33 covers part of the width of the active region 30, the effective width is now the width of the active region 30 less than width of the p-type cap layer 33. The overall resistance of this structure is determined based on the length from the first port 31 to the second port 32, the width of the active region 30 and the semiconductor sheet resistance of the active region 30. By decreasing the effective width of the active region 30, the resistance of the structure is increased. Additionally, using this technique, a shorter active region may be used to create the same resistance.

This structure has many advantages. As noted above, by the use of p-type cap layers, the width of the active region of a semiconductor structure, such as a transistor, diode or semiconductor resistor, may be reduced. Thus, the width can be reduced to sub-micron dimensions which otherwise will not be available using the conventional isolation method alone. The process design rules of a foundry may limit the minimum width of the active region formed by implant isolation to features in the range of 1-10 um. The minimum effective width when using two regions of p-type cap layer is typically defined as the minimum feature space, which may be in the range of 0.1 um-5 um. The minimum effective width when using one region of p-type cap is typically defined as the minimum active to p-type cap surround dimensions, which may be in the range of 0.1 um-2 um. Thus, as long as one of these two latter minimum dimensions is smaller than the minimum allowed active region width, a smaller effective width can be achieved using this structure.

Furthermore, the disclosure is not limited to III-Nitride structures. This is also applicable to silicon based MOSFETS (metal-oxide-semiconductor field-effect-transistor), LDMOS (laterally-diffused MOS), silicon carbide transistors, and GaAs devices.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A semiconductor transistor for use in a III-Nitride (III-N) semiconductor device, comprising:
a channel layer;
a barrier layer located on the channel layer in a height direction, wherein electrons are formed at an interface between the channel layer and the barrier layer;
a source electrode and a drain electrode, wherein a direction between the source electrode and the drain electrode is a length direction; and
a gate electrode disposed between the source electrode and the drain electrode in the length direction and extending in a width direction, defining a gate region;
such that the gate region comprises one or more depletion mode gate regions and one or more enhancement mode gate regions.

2. The semiconductor transistor of claim 1, wherein an effective width of the semiconductor transistor is equal to a width of the one or more depletion mode gate regions.

3. The semiconductor transistor of claim 1, further comprising a p-type cap layer disposed on a portion of the barrier layer in the gate region to create the one or more enhancement mode gate regions.

4. The semiconductor transistor of claim 3, wherein the p-type cap layer comprises a Mg-doped GaN layer.

5. The semiconductor transistor of claim 3, wherein the gate electrode is electrically isolated from the p-type cap layer.

6. The semiconductor transistor of claim 3, wherein the gate electrode does not extend over the p-type cap layer.

7. The semiconductor transistor of claim 3, wherein the gate electrode extends over the p-type cap layer and is electrically connected to the p-type cap layer.

8. The semiconductor transistor of claim 7, wherein the one or more depletion mode gate regions are enabled when a voltage applied to the gate electrode is greater than a negative threshold voltage (Vtd) and the one or more enhancement mode gate regions are enabled when the voltage applied to the gate electrode is greater than a positive threshold voltage (Vte), and wherein the voltage applied to the gate electrode is switched between a voltage that is less than the negative threshold voltage and a voltage that is greater than the negative threshold voltage and less than the positive threshold voltage.

9. The semiconductor transistor of claim 1, wherein the gate region comprises two enhancement mode gate regions disposed on opposite sides of the depletion mode gate region in the width direction.

10. The semiconductor transistor of claim 1, wherein the gate region comprises one enhancement mode gate region adjacent to the depletion mode gate region in the width direction.

11. The semiconductor transistor of claim 1, wherein the gate region comprises two depletion mode gate regions disposed on opposite sides of the enhancement mode gate region in the width direction.

12. The semiconductor transistor of claim 1, wherein the enhancement mode gate region is created by etching to partially or completely remove the barrier layer in a portion of the gate region.

13. A semiconductor diode for use in a III-Nitride (III-N) semiconductor device, comprising:
a channel layer;
a barrier layer located on the channel layer in a height direction, wherein electrons are formed at an interface between the channel layer and the barrier layer;
a anode and a cathode, wherein a region between the anode and the cathode is an active region; and
a p-type cap layer disposed on top of a portion of the active region extending from the anode to the cathode.

14. The semiconductor diode of claim 13, wherein an effective width of the semiconductor diode is equal to a width of the active region less the width of the p-type cap layer.

15. The semiconductor diode of claim 13, wherein the p-type cap layer is disposed on both side of the active region in a width direction.

16. A semiconductor resistor for use in a III-Nitride (III-N) semiconductor device, comprising:
a first port and a second port;
a channel layer;
a barrier layer located on the channel layer in a height direction, wherein electrons are formed at an interface between the channel layer and the barrier layer;
wherein a region between the first port and the second port defines an active region; and
a p-type cap layer disposed on top of a portion of the active region extending from the first port to the second port; wherein a resistance of the semiconductor resistor is determined based on a length of the active region, wherein the length is defined as a distance from the first port to the second port, an effective width of the active region and a sheet resistance of the active region.

17. The semiconductor resistor of claim 16, wherein the p-type cap layer is disposed on both sides of the active region in a width direction.

18. The semiconductor resistor of claim 16, wherein the p-type cap layer is disposed on one side of the active region in a width direction.

19. The semiconductor resistor of claim 16, wherein the effective width of the active region is equal to a width of the active region less the width of the p-type cap layer.
